(19) United States
(12) Patent Application Publication
(10) Pub. No.: US 2013/0168657 A1
(43) Pub. Date: Jul. 4, 2013

(54) THIN FILM TRANSISTOR ON FIBER AND METHOD OF MANUFACTURING THE SAME

(71) Applicant: SAMSUNG ELECTRONICS CO., LTD., Suwon-shi (KR)

(72) Inventors: Chwee Lin CHOONG, Suwon-si (KR); Jung-kyun IM, Yongin-si (KR); Jong-jin PARK, Hwaseong-si (KR); Jae-hyun HUR, Yongin-si (KR)

(73) Assignee: SAMSUNG ELECTRONICS CO., LTD., Suwon-si (KR)

(21) Appl. No.: 13/734,552

(22) Filed: Jan. 4, 2013

(30) Foreign Application Priority Data
Jan. 4, 2012 (KR) 10-2012-0001147

(51) Int. Cl. H01L 51/05; H01L 51/00

(52) U.S. Cl. CPC H01L 51/0558; H01L 51/0001
USPC 257/40; 438/99

(57) ABSTRACT

A thin film transistor formed on a fiber and method of manufacturing the same. The thin film transistor includes a fiber; a first electrode that is disposed on the fiber; a second electrode that is disposed on the fiber and space apart from the first electrode; a gate electrode that is disposed on the fiber; a channel that is disposed between the first electrode and the second electrode; and a gate insulating layer that is disposed on the first electrode, the second electrode, the gate electrode and the channel; and an encapsulant that encapsulates the gate insulating layer.

### CROSS-REFERENCE TO RELATED APPLICATION

This application claims the benefit of Korean Patent Application No. 10-2012-0001147, filed on Jan. 4, 2012, in the Korean Intellectual Property Office, the disclosure of which is incorporated herein in its entirety by reference.

### BACKGROUND

1. Field

The present disclosure relates to fiber transistors, and more particularly, to fiber transistors and methods of manufacturing the same.

2. Description of the Related Art

As the application field of electronic devices broadens, there is an increasing demand for flexible electronic devices which may overcome limitations of conventional electronic devices formed on substrates such as silicon (Si) and glass substrates. Thin film transistors (TFTs) used in fields such as flexible displays, smart clothing, dielectric elastomer actuators (DEA), biocompatible electrodes, and electronic devices used to detect electric signals in a living body need to be flexible and foldable. In particular, in order to manufacture a foldable TFT, each element constituting the transistor needs to be flexible.

### SUMMARY

One or more embodiments provide a thin film transistor formed on a fiber.

One or more embodiments also provide a method of manufacturing a thin film transistor formed on a fiber.

According to an aspect of an embodiment, there is provided a thin film transistor including: a fiber; a first electrode that is disposed on the fiber; a second electrode that is disposed on the fiber and space apart from the first electrode; a gate electrode that is disposed on the fiber; a channel that is disposed between the first electrode and the second electrode; and a gate insulating layer that is disposed on the first electrode, the second electrode, the gate electrode and the channel; and an encapsulant that encapsulates the gate insulating layer.

The fiber may be a natural fiber, a chemical fiber, or any mixture thereof.

The fiber may be a single fiber.

The channel may be a semiconductor thin film formed of an organic semiconductor material or a nanostructure with a fiber shape.

The organic semiconductor material may include polythiophene, polyacetylene, polypyrrole, polyphenylene, polythienyl vinylidene, polyphenylene sulfide, polyaniline, polyparaphenylene vinylene, polyparaphenylene, polyfluorene, or polythiovinylene.

The gate insulating layer may be formed of a mixture of ionic liquids or electrolytes with a resin.

The encapsulant may be a resin or a mold-forming material.

The resin may be a thermosetting or UV-curable acrylic resin, a thermosetting epoxy resin, or an elastomer resin.

The thin film transistor may be used in flexible displays, smart clothing, dielectric elastomer actuators (DEA), biocompatible electrodes or electronic devices used to detect electric signals in a living body need to be flexible and foldable.

According to an aspect of another embodiment, there is provided a method of manufacturing a thin film transistor, the method including depositing a conductive material on a fiber and patterning the deposited conductive material to form a first electrode, a second electrode, and a gate electrode on the fiber; forming a channel between the first electrode and the second electrode; forming a side wall of an encapsulant on the fiber, the first electrode, the second electrode, and the gate electrode; forming a gate insulating layer inside the side wall of the encapsulant; and forming a cover layer of the encapsulant on the gate insulating layer so that the gate insulating layer is encapsulated by the sidewall and the cover layer of the encapsulant.

### BRIEF DESCRIPTION OF THE DRAWINGS

The above and/or other aspects will become apparent and more readily appreciated from the following description of embodiments, taken in conjunction with the accompanying drawings in which:

FIG. 1 shows a structure of a thin film transistor (TFT) formed on a fiber, according to an embodiment;

FIGS. 2 to 6 are diagrams for describing a method of manufacturing a TFT formed on a fiber, according to an embodiment; and

FIG. 7 is a plan view of a TFT formed on a fiber, according to an embodiment.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

Hereinafter, a thin film transistor (TFT) formed on a fiber, according to an embodiment, will be described in detail with reference to the drawings. In the accompanying drawings, thicknesses and sizes of layers or regions are exaggerated for clarity.

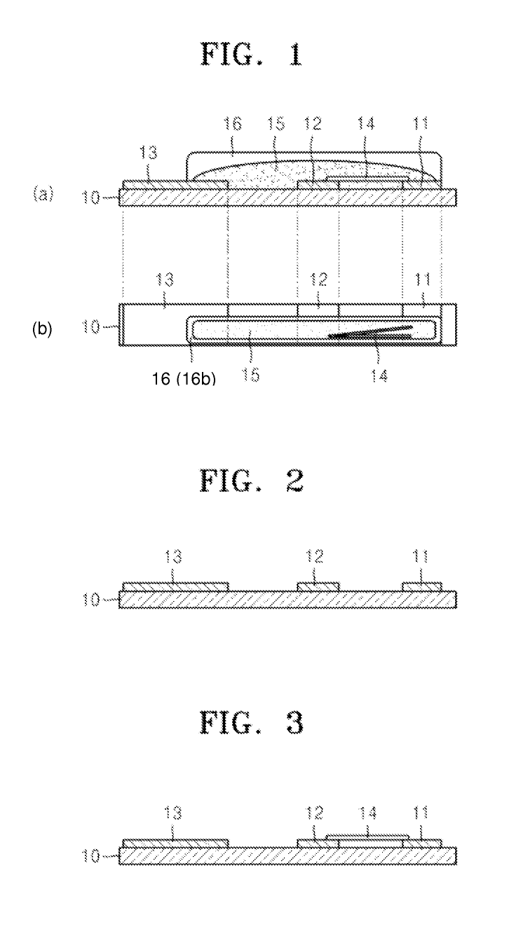

FIG. 1 shows a structure of a TFT formed on a fiber 10, according to an embodiment of the present invention. In FIG. 1, (a) is a cross-sectional view of the TFT, and (b) is a plan view of the TFT.

The TFT formed on the fiber according to the current embodiment includes the fiber 10 and a first electrode 11, a second electrode 12, and a gate electrode 13 which are formed on the fiber 10 and spaced apart from one another. The first electrode 11 and the second electrode 12 may be respectively a drain electrode and a source electrode, and the reverse is also possible. A channel 14 is formed between the first electrode 11 and the second electrode 12. A gate insulating layer 15 may be formed on the fiber 10, the first electrode 11, the second electrode 12, the gate electrode 13 and the channel. The gate insulating layer 15 may be encapsulated by an encapsulant 16 formed on the fiber 10, the first electrode 11, the second electrode 12, and the gate electrode 13.

In this regard, the fiber 10 may function as a substrate and may include a natural fiber, a chemical fiber, or any combination thereof with excellent smoothness, water resistance, tensile strength, and bending property. For example, the natural fiber may be produced from wood pulp, hemp, ramie, hemp cloth, or wool, and the chemical fiber may be produced from vinylon, nylon, acryl, rayon, polypropylene, or asbestos fiber. The fiber 10 may be a single fiber with various cross-section shapes such as a circular, oval, and polygonal, e.g., rectangular, cross-sections. The fiber 10 may have a length of a cross-section that is more than several times to several tens of times, for example, 100 to 1000 times, longer than a width of the cross-section.

The first electrode 11, the second electrode 12, and the gate electrode 13 may be formed of a conductive material, for example, metal, a conductive metal oxide, or a conductive polymer. For example, the metal may include aluminum (Al), gold (Au), silver (Ag), chromium (Cr), titanium (Ti), copper (Cu), tantalum (Ta), molybdenum (Mo), tungsten (W), nickel (Ni), palladium (Pd), platinum (Pt), or any alloy thereof. The conductive metal oxide may include indium tin oxide (ITO), indium zinc oxide (IZO), and the like. The conductive polymer may include polyethylene dioxythiophene:polystyrene sulphonate (PEDOT:PSS), polyaniline, polypyrrole, or any mixture thereof.

The channel 14 that is disposed between the first electrode 11 and the second electrode 12 may be a semiconductor thin film formed of an organic semiconductor material or a nanostructure with a fiber shape. The shape of the nanostructure is not limited, and may be, for example, a one-dimensional structure with a circular or polygonal cross-section. For example, the organic semiconductor material may include polythiophene, polyacetylene, polypyrrole, polyphenylene, polythienyl vinylidene, polyphenylene sulfide, polyaniline, polyparaphenylene vinylene, polyparaphenylene, polyfluorene, or polythio vinylene, and the like.

The gate insulating layer 15 is formed on the fiber 10 and on the first electrode 11, the second electrode 12, and the gate electrode 13, which are formed on the fiber 10, and the channel 14, and may be formed of a mixture of ionic liquids or electrolytes and a resin, or a gel-like polymer. As such, the resin mixed with ionic liquids has dielectric properties, is flexible, and has a high adhesion to a substrate.

In this regard, the ionic liquid is a salt including cations and anions in a liquid state. For example, the cations of the ionic liquid may include imidazolium, pyrazolium, triazolium, thiazolium, oxazolium, pyridazinium, pyrimidinium, pyrazinium, ammonium, phosphonium, guanidinium, uronium, thiouronium, pyridinium, pyrroldinium, or any mixture thereof. In addition, the anions of the ionic liquid may include halides, borate-based anions, phosphate-based anions, phosphinate-based anions, imide-based anions, sulfonate-based anions, acetate-based anions, sulfate-based anions, cyanate-based anions, thiocyanate-based anions, carbon-based anions, complex-based anions, or ClO₄⁻.

In addition, the resin used to form the gate insulating layer 15 may be a UV-curable acrylic resin, a thermosetting epoxy resin, or an elastomer resin. For example, the resin may include poly(ethylene glycol) diacrylate, trimethylolpropane triacrylate, and dipentaerythritol hexaacrylate. The mixture of ionic liquids and a resin are cured to form an elastic gate insulating layer. The gate insulating layer 15 formed of the mixture of ionic liquids and the resin may be flexible.

The encapsulant 16 may encapsulate the material used to form the gate insulating layer 15 and may include a resin or a mold-forming material. For example, the resin may be a thermosetting or UV-curable acrylic resin, a thermosetting epoxy resin, or an elastomer resin and may include poly(ethylene glycol)diacrylate, trimethylolpropane triacrylate, and dipentaerythritol hexaacrylate.

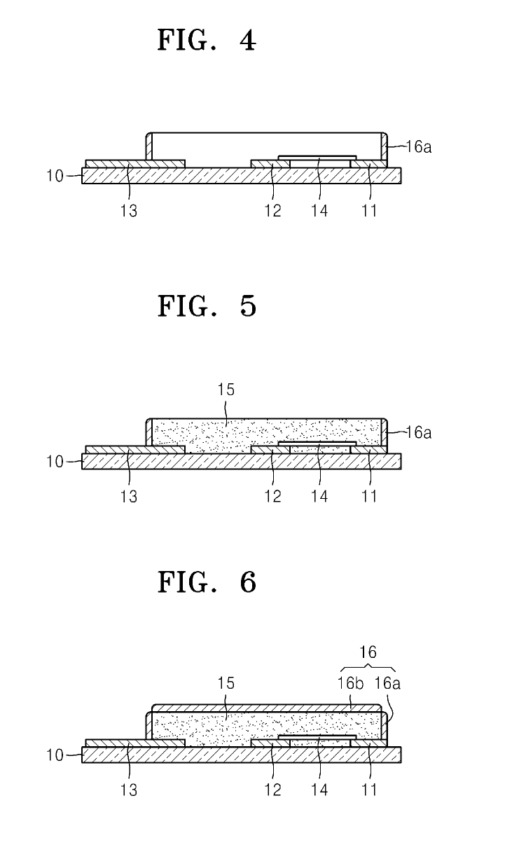

Hereinafter, a method of manufacturing a TFT formed on a fiber, according to another embodiment of the present invention, will be described with reference to the drawings. FIGS. 2 to 6 are diagrams for describing a method of manufacturing a TFT formed on a fiber, according to an embodiment of the present invention.

Referring to FIG. 2, first, a fiber 10 is prepared. The fiber 10 may be a natural fiber, a chemical fiber, and any mixture thereof, and the length of the fiber 10 may be far greater than the width. The TFT may be formed on a single strand of the fiber 10. A conductive material is deposited on the fiber 10 and patterned to form the first electrode 11, the second electrode 12, and the gate electrode 13. The conductive material may be metal, a conductive metal oxide, or a conductive polymer. The conductive material may be deposited on the fiber 10 by using physical vapor deposition, chemical vapor deposition (CVD), or the like without limitation. The first electrode 11, the second electrode 12, and the gate electrode 13 may be formed of the same material at the same time, and the material may be arbitrarily selected.

Referring to FIG. 3, the channel 14 is disposed between the first electrode 11 and the second electrode 13. The channel 14 may be a semiconductor thin film formed of an organic semiconductor material or a nanostructure with a fiber shape. The organic semiconductor material may include polythiophene, polyacetylene, polypyrrole, polyphenylene, polythienyl vinylidene, polyphenylene sulfide, polyaniline, polyparaphenylene vinylene, polyparaphenylene, polyfluorene, or polythiovinylene, and the like. For example, the channel 14 may be formed by electrospinning a nanofiber of poly-3(hexylthiophene) (P3HT).

Referring to FIG. 4, a side wall 16a of the encapsulant 16 is formed in order to form the gate insulating layer 15 of FIG. 1. The side wall 16a is formed to prevent a liquid or gel material forming the gate insulating layer 15 from leaking out. As shown in (b) of FIG. 1, the side wall 16a is formed on the fiber 10, the first electrode 11, the second electrode 12, the gate electrode 13 and the channel 14 to surround the outer circumference of a region where the gate insulating layer 15 is formed. The encapsulant 16 may be formed of a resin or a mold-forming material. For example, the resin may be a thermosetting or UV-curable acrylic resin, a thermosetting epoxy resin, or an elastomer resin and may include poly(ethylene glycol)diacrylate, trimethylolpropane triacrylate, and dipentaerythritol hexaacrylate.

Referring to FIG. 5, the gate insulating layer 15 is formed inside the side wall 16a. The gate insulating layer 15 may be formed of a mixture of ionic liquids or electrolytes with a resin or a gel-like polymer.

Referring to FIG. 6, the gate insulating layer 15 is formed inside the side wall 16a, and then a cover layer 16b of the encapsulant 16 is formed on the gate insulating layer 15. The cover layer 16b of the encapsulant 16 may be formed of a resin or a mold-forming material, for example, a thermosetting or UV-curable acrylic resin, a thermosetting epoxy resin, or an elastomer resin.

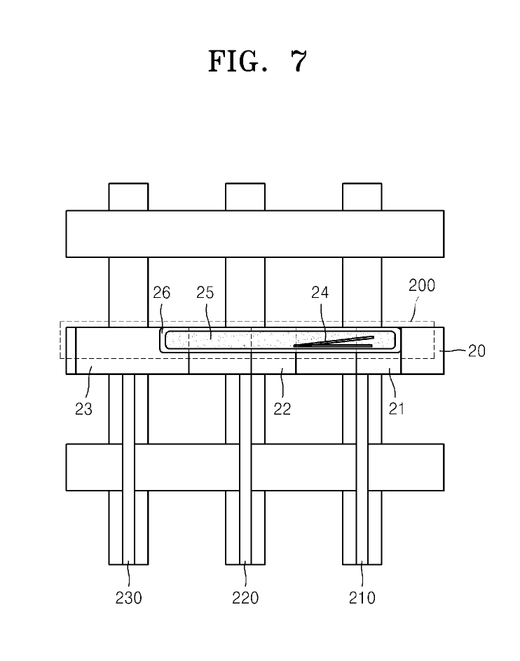

FIG. 7 is a plan view of a TFT 200 formed on a fiber 20, which is one of a plurality of fibers 20, according to an embodiment of the present invention.

Referring to FIG. 7, a first electrode 21, a second electrode 22, and a gate electrode 23 are formed on the fiber 20, and a channel 24 is formed on the first electrode 21 and the second electrode 22. In addition, a gate insulating layer 25 is formed on the fiber 20, the first electrode 21, the second electrode 22, the gate electrode 23 and the channel 24, and the gate insulating layer 25 is encapsulated by using an encapsulant 26. The first electrode 21 and the second electrode 22 are electrically connected to a first electrode bus line 210 and a second electrode bus line 220, respectively, which are external bus lines. The gate electrode 23 is electrically connected to a gate connection line 230.

According to one or more embodiments, a TFT that is formed on a single fiber and has stable characteristics may be provided.

In addition, according to one or more embodiments, there is provided a method of efficiently manufacturing a TFT formed on a single fiber.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A thin film transistor comprising:
a fiber;
a first electrode that is disposed on the fiber;
a second electrode that is disposed on the fiber and space apart from the first electrode;
a gate electrode that is disposed on the fiber;
a channel that is disposed between the first electrode and the second electrode; and
a gate insulating layer that is disposed on the first electrode, the second electrode, the gate electrode and the channel.

2. The thin film transistor of claim 1 further comprising an encapsulant that encapsulates the gate insulating layer.

3. The thin film transistor of claim 1, wherein the fiber is a natural fiber, a chemical fiber, or a mixture natural and chemical fibers.

4. The thin film transistor of claim 3, wherein the fiber is a single fiber.

5. The thin film transistor of claim 1, wherein the channel is a semiconductor thin film comprising an organic semiconductor material or a nanostructure with a fiber shape.

6. The thin film transistor of claim 5, wherein the organic semiconductor material comprises polythiophene, polyacetylene, polypyrrole, polyphenylene, polythienyl vinylidene, polyphenylene sulfide, polyaniline, polyparaphenylene vinylene, polyparaphenylene, polyfluorene, or polythiovinylene.

7. The thin film transistor of claim 1, wherein the gate insulating layer is comprises a mixture of ionic liquids or electrolytes with a resin.

8. The thin film transistor of claim 2, wherein the encapsulant is a resin or a mold-forming material.

9. The thin film transistor of claim 8, wherein the resin is a thermosetting acrylic resin, a UV-curable acrylic resin, a thermosetting epoxy resin, or an elastomer resin.

10. A method of manufacturing a thin film transistor, the method comprising:
depositing a conductive material on a fiber and patterning the deposited conductive material to form a first electrode, a second electrode, and a gate electrode on the fiber;
forming a channel between the first electrode and the second electrode;
forming a side wall of an encapsulant on the fiber, the first electrode, the second electrode, and the gate electrode;
forming a gate insulating layer inside the side wall of the encapsulant; and
forming a cover layer of the encapsulant on the gate insulating layer so that the gate insulating layer is encapsulated by the sidewall and the cover layer of the encapsulant.

11. The method of claim 10, wherein the fiber is a natural fiber, a chemical fiber, or a mixture natural and chemical fibers.

12. The method of claim 11, wherein the fiber is a single fiber.

13. The method of claim 10, wherein the channel is a semiconductor thin film comprising an organic semiconductor material or a nanostructure with a fiber shape.

14. The method of claim 13, wherein the organic semiconductor material comprises polythiophene, polyacetylene, polypyrrole, polyphenylene, polythienyl vinylidene, polyphenylene sulfide, polyaniline, polyparaphenylene vinylene, polyparaphenylene, polyfluorene, or polythiovinylene.

15. The method of claim 10, wherein the gate insulating layer is comprises a mixture of ionic liquids or electrolytes with a resin.

16. The method of claim 10, wherein the encapsulant is a resin or a mold-forming material.

17. The method of claim 16, wherein the resin is a thermosetting acrylic resin, a UV-curable acrylic resin, a thermosetting epoxy resin, or an elastomer resin.
